(19) United States
(12) Patent Application Publication
(10) Pub. No.: US 2009/0081383 A1
(43) Pub. Date: Mar. 26, 2009

(54) Carbon Nanotube Infused Composites via Plasma Processing

(75) Inventors: Mark R. Alberding, Glen Arm, MD (US); Tushar K. Shah, Columbia, MD (US); James A. Waicukauski, Bel Air, MD (US); Jordan T. Ledford, Hampstead, MD (US); Harry C. Malecki, Middle River, MD (US); Jack Braine, Mohnton, PA (US); John A. LaRue, Bel Air, MD (US)

Correspondence Address: Lockheed Martin c/o;DEMONT & BREYER, LLC, 100 COMMONS WAY, Ste. 250, HOLMDEL, NJ, 07733, US

(73) Assignee: Lockheed Martin Corporation, Bethesda, MD (US)

(21) Appl. No.: 12/235,301

(22) Filed: Sep. 22, 2008

Related U.S. Application Data
(60) Provisional application No. 60/973,966, filed on Sep. 20, 2007.

(51) Int. Cl. C23C 16/26; H05H 1/24

(52) U.S. Cl. 427/577; 118/723 R; 977/844

(57) ABSTRACT

A continuous, plasma-based process for the production of carbon-nanotube-infused fibers is disclosed.

### STATEMENT OF RELATED CASES

This case claims priority of U.S. patent application Ser. No. 11/619,327 filed on Jan. 3, 2007 and U.S. Provisional Pat. App. Ser. No. 60/973,966 filed on Sep. 20, 2007.

### FIELD OF THE INVENTION

The present invention relates to carbon nanotubes, fibers, and fiber-reinforced composite materials.

### BACKGROUND OF THE INVENTION

Fibers are used for many different applications in a wide variety of industries, including aerospace, recreation, industrial and transportation industries. Commonly-used fibers for these and other applications include cellulosic fiber (e.g., viscose rayon, cotton, etc.), glass fiber, carbon fiber, and aramid fiber, to name just a few.

In many fiber-containing products, the fibers are present in the form of a composite material (e.g., fiberglass, etc.). A composite material is a heterogeneous combination of two or more constituents that differ in form or composition on a macroscopic scale. While the composite material exhibits characteristics that neither constituent alone possesses, the constituents retain their unique physical and chemical identities within the composite.

Two key constituents of a fiber-reinforced polymer matrix composite (PMC) are a reinforcing agent and a resin matrix. In a fiber-based composite, the fibers are the reinforcing agent. The resin matrix keeps the fibers in a desired location and orientation and also serves as a load-transfer medium between fibers within the composite.

Fibers are characterized by certain properties, such as mechanical strength, density, electrical resistivity, thermal conductivity, etc. The fibers “lend” their characteristic properties, in particular their strength-related properties, to the composite. Fibers therefore play an important role in determining a composite's suitability for a given application.

To realize the benefit of fiber properties in a composite, there must be good interfacial strength between the fibers and the matrix. This is achieved through the use of a surface coating, typically referred to as “sizing.” The sizing provides an all important physico-chemical link between fiber and the resin matrix and thus has a significant impact on the mechanical and chemical properties of the composite. The sizing is applied to fibers during their manufacture.

Substantially all conventional sizing has lower interfacial strength than the fibers to which it's applied. As a consequence, the strength of the sizing and its ability to withstand interfacial stress ultimately determines the strength of the overall composite. In other words, using conventional sizing, the resulting composite cannot have a strength that is equal to or greater than that of the fiber.

### SUMMARY

The present invention provides a continuous, plasma-based process for the production of carbon nanotube infused fibers.

In U.S. patent application Ser. No. 11/619,327, applicant disclosed a CNT-infused fiber. Unlike prior-art processes, in the CNT-infused fiber disclosed in the '327 application, the carbon nanotubes are “infused” to the parent fiber. The term “infused” means physically or chemically bonded to the parent fiber such that the carbon nanotubes are an integral part of the fiber and are themselves load-carrying.

Regardless of its true nature, the bond that is formed between the carbon nanotubes and the parent fiber is quite robust and is responsible for CNT-infused fiber being able to exhibit or express carbon nanotube properties or characteristics. This is in stark contrast to some prior-art processes, wherein nanotubes are suspended/dispersed in a solvent solution and applied, by hand, to fiber. Because of the strong van der Waals attraction between the already-formed carbon nanotubes, it is extremely difficult to separate them to apply them directly to the fiber. As a consequence, the lumped nanotubes weakly adhere to the fiber and their characteristic nanotube properties are weakly expressed, if at all.

According to the '327 application, nanotubes are synthesized in place on the parent fiber itself. This is important; if the carbon nanotubes are not synthesized on the fiber, they will become highly entangled and infusion does not occur. As seen from the prior art, non-infused carbon nanotubes impart little if any of their characteristic properties.

As described in the '327 application, the parent fiber can be any of a variety of different types of fibers, including, without limitation: carbon fiber, graphite fiber, metallic fiber (e.g., steel, aluminum, etc.), ceramic fiber, metallic-ceramic fiber, glass fiber, cellulosic fiber, aramid fiber. The '327 application further discloses that nanotubes are synthesized on the parent fiber by applying or infusing a nanotube-forming catalyst, such as iron, nickel, cobalt, or a combination thereof, to the fiber.

The '327 application disclosed certain operations of the CNT-infusion process, including (1) the removal of sizing from the parent fiber; (2) applying nanotube-forming catalyst to the parent fiber; (3) heating the fiber to nanotube-synthesis temperature; and (4) spraying carbon plasma onto the catalyst-laden parent fiber.

The '327 application references methods and techniques for forming carbon nanotubes, as disclosed in Published Pat. Application No. US 2004/0245088. In the illustrative embodiment, acetylene gas is ionized to create a jet of cold carbon plasma. The plasma is directed toward the catalyst-bearing parent fiber.

The commercial success of CNT-infused composite materials, however, awaits the development of a tightly-controlled, rapid, cost-effective, and scaleable manufacturing process.

In accordance with the illustrative embodiment, a continuous and linear manufacturing process is disclosed that utilizes plasma processing for:
Fiber surface modification (to achieve the morphology required to infuse catalyst nano particles in/on the fibers);
Application of the catalyst in/on the fibers; and
Growth of carbon nanotubes in/on the fibers.

### BRIEF DESCRIPTION OF THE DRAWING

FIG. 1 depicts the illustrative embodiment of manufacturing line 100 for producing CNT-infused fiber.

### DETAILED DESCRIPTION

All patent applications and patents referenced in this specification are incorporated by reference herein. As used herein, the terms “filament” and “fiber” are synonymous.

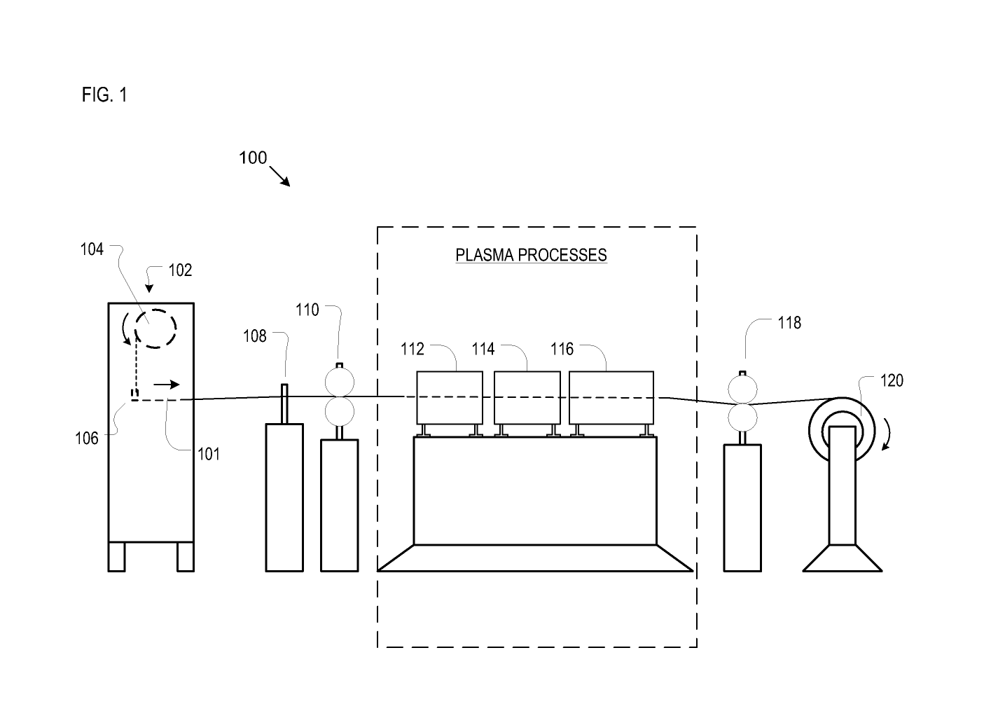

FIG. 1 depicts the illustrative embodiment of manufacturing line 100 for producing CNT-infused fiber. As depicted, manufacturing line 100 includes the following processes or operations: fiber tensioning and payout 102, fiber spreading 108, first nip rolls 110; fiber surface modification 112, catalyst application 114, CNT-growth reactor 116, second nip rolls 118; and fiber take-up spooling system 120, arranged as shown.

Line 100 processes a plurality of filaments or fibers, which are collectively referred to as a “fiber tow.” The tow can include any number of fibers; for example, in some embodiments of the present invention, the tow includes 12,000 fibers.

Fiber tensioning and payout station 102 includes payout bobbin 104 and tensioner 106. The payout bobbin delivers fibers 101 to the process; the fibers are tensioned via tensioner 106.

Fibers 101 are delivered to fiber spreader station 108. The fiber spreader separates the fibers. In the illustrative embodiment, the fiber spreader is an air knife. In other embodiments, various well-known techniques and apparatuses can be used to spread fiber. Spreading the fibers enhances the effectiveness of downstream operations, such as catalyst application and plasma application, by exposing more fiber surface area.

The spread fibers are delivered to first nip roll station 110. The nip rolls maintain the spread of the fibers. Fiber tensioning and payout 102, fiber spreading 108 and nip rolls 110 are standard fiber-processing equipment; those skilled in the art will be familiar with their design and use.

The fibers then enter the first of the plasma processes, fiber surface modification 112. This is a plasma process for “roughing” the surface of the fibers to facilitate catalyst deposition. The roughness is typically on the scale of nanometers; that is, craters or depressions are formed that are nanometers deep and nanometers in diameter. Surface modification can be achieved using a plasma of any one or more of a variety of different gases, including, without limitation, argon, helium, oxygen, and ammonia.

After surface modification, the fibers proceed to catalyst application 114. This is a plasma process for depositing the CNT-forming catalyst on the fibers. The catalyst is typically a transition metal (e.g., iron, iron oxide, nickel, cobalt, ytterium, etc., and combinations thereof). These transition metal catalysts are readily commercially available from a variety of suppliers, including Ferrotech of Nashua, N.H.

The transition metal catalyst is typically added to the plasma feedstock gas as a precursor in the form of a ferrofluid, a metal organic, metal salt or other composition for promoting gas phase transport. The catalyst can be applied at room temperature in the ambient environment (neither vacuum nor an inert atmosphere is required). In some embodiments, the fibers are cooled prior to catalyst application.

In the illustrative embodiment, carbon nanotube synthesis occurs in CNT-growth reactor 116. This is also a plasma-based process (e.g., plasma-enhanced chemical vapor deposition, etc.) wherein carbon plasma is sprayed onto the catalyst-laden fibers.

Since carbon nanotube growth occurs at elevated temperatures (typically in a range of about 500 to 1000° C. as a function of the catalyst), the catalyst-laden fibers are first heated. For the infusion process, the fibers should be heated until they soften. Generally, a good estimate of the softening temperature for any particular type of fiber is readily obtained from reference sources, as is known to those skilled in the art. To the extent that this temperature is not a priori known for a particular fiber, it can be readily determined by experimentation. The fibers are typically heated to a temperature that is in the range of about 500 to 1000° C. Any of a variety of heating elements can be used to heat the fibers, such as, without limitation, infrared heaters, a muffle furnace, and the like.

After heating, the fibers are ready to receive the carbon plasma. The carbon plasma is generated, for example, by passing a carbon containing gas (e.g., acetylene, ethylene, ethanol, etc.) through an electric field that is capable of ionizing the gas. This cold carbon plasma is directed, via spray nozzles, to the fibers. The fibers are within about 1 centimeter of the spray nozzles to receive the plasma. In some embodiments, heaters are disposed above the fibers at the plasma sprayers to maintain the elevated temperature of the fiber. As a consequence of the exposure of the catalyst to the carbon plasma, Carbon nanotubes grow on the fibers.

After CNT-infusion, CNT-infused fibers pass through second nip rolls 118 for maintaining fiber spread, and then spooled at fiber take-up spooling station 120. CNT-infused fiber is then ready for use in any of a variety of applications, including, without limitation, for use as the reinforcing material in composite materials.

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. A process for producing CNT-infused fiber, the process comprising:
modifying the surface of a fiber by exposing the fiber to a plasma jet;
applying, via a plasma process, a transition-metal catalyst to the modified fiber; and
growing carbon nanotubes on the catalyst-laden fiber by applying a carbon plasma to the catalyst-laden fiber, wherein the fiber is continuously in motion during the modifying, applying and growing operations.

2. An apparatus comprising:
means for modifying the surface of a fiber via a plasma; and
means for applying a transition-metal catalyst to the modified fiber via a plasma; means for growing carbon nanotubes on the catalyst-laden fiber via a carbon plasma; and
means for keeping the fiber in constant motion while the surface is modified, the transition metal catalyst is applied, and the carbon nanotubes are grown.
